(19) United States
(12) Patent Application Publication
(10) Pub. No.: US 2024/0186777 A1
(43) Pub. Date: Jun. 6, 2024

(54) ELECTRICAL JUNCTION BOX

(71) Applicant: SUMITOMO WIRING SYSTEMS, LTD., Mie (JP)

(72) Inventor: Shunsuke KATSUSE, Mie (JP)

(21) Appl. No.: 18/285,616

(22) PCT Filed: Mar. 17, 2022
(86) PCT No.: PCT/JP2022/012354

§ 371 Date: Oct. 4, 2023

(30) Foreign Application Priority Data
Apr. 9, 2021 (JP) 2021-066188

(51) Int. Cl. H02G 3/08; H02G 3/16

(52) U.S. Cl. CPC H02G 3/081; H02G 3/086; H02G 3/16

(57) ABSTRACT

Improvement of workability during assembly is intended. An electrical junction box (A) includes a base member (10) to which electrical components (66) are to be attached and a pair of left and right side wall members (40) detachably attached to the base member (10), a component housing chamber (65) whose upper surface is open is formed by the base member (10) and the pair of side wall members (40), the electrical components (66) attached to the base member (10) are housed in the component housing chamber (65), and side surfaces of the component housing chamber (65) are open in a state where the side wall members (40) are detached from the base member (10).

### TECHNICAL FIELD

The present disclosure relates to an electrical junction box.

### BACKGROUND

Patent Document 1 discloses a structure for mounting cutoff elements within a cutoff element housing portion formed in a connection box body. The cutoff element housing portion is a space that is open at the upper surface of the connection box body, and the cutoff elements are fitted in the cutoff element housing portion from above the connection box.

### PRIOR ART DOCUMENT

### Patent Document

Patent Document 1: JP 2021-002441 A

### SUMMARY OF THE INVENTION

### Problems to be Solved

In the above-described structure, the peripheral wall portions of the cutoff element housing portion surround the entire circumference of electric components from the front, rear, left, and right directions. Therefore, when a cutoff element is manually pinched and mounted to the cutoff element housing portion, the fingers pinching the cutoff element may interfere with the peripheral wall portions.

The electrical junction box of the present disclosure has been completed in the light of the above-described circumstances, and an object thereof is to improve the workability during assembly.

### Means to Solve the Problem

An electrical junction box of the present disclosure includes:
a base member to which an electrical component is to be attached; and
a pair of left and right side wall members capable of being detachably attached to the base member;
wherein a component housing chamber whose upper surface is open is formed by the base member and the pair of side wall members,
the electrical component attached to the base member is housed in the component housing chamber, and
side surfaces of the component housing are open in a state where the side wall members are detached from the base member.

### Effect of the Invention

According to the present disclosure, the workability during assembly is improved.

### BRIEF DESCRIPTION OF THE DRAWINGS

FIG. 1 is a perspective view of an electrical junction box of a first embodiment as seen obliquely from the upper front side.

FIG. 2 is a perspective view of the electrical junction box as seen obliquely from the upper rear side.

FIG. 3 is a perspective view of the electrical junction box separated into a base member and side wall members as seen obliquely from the upper front side.

FIG. 4 is a perspective view of the electrical junction box separated into the base member and the side wall members as seen obliquely from the upper rear side.

FIG. 5 is a perspective view of how electrical components are attached to the base member from above as seen obliquely from the upper front side.

FIG. 6 is a perspective view of the side wall members separated into main side wall bodies and busbars as seen obliquely from the lower front side.

### DETAILED DESCRIPTION TO EXECUTE THE INVENTION

### Description of Embodiments of the Present Disclosure

First, embodiments of the present disclosure will be listed and described.

(1) An electrical junction box of the present disclosure includes: a base member to which an electrical component is to be attached; and a pair of left and right side wall members capable of being detachably attached to the base member; wherein a component housing chamber whose upper surface is open is formed by the base member and the pair of side wall members, the electrical component attached to the base member is housed in the component housing chamber, and side surfaces of the component housing are open in a state where the side wall members are detached from the base member. According to this configuration, by detaching the side wall members in advance when mounting the electrical component to the base member, the side wall members do not become a hinderance. Therefore, the workability during assembly is improved.

(2) Preferably, connecting members are attached to the base member, a busbar is mounted to each of the side wall members, and a direction in which the side wall members are assembled to the base member is the same as a direction in which the busbars are respectively assembled to the connecting members. According to this configuration, the connecting members and the busbars can be connected to each other by assembling the side wall members to the base member.

(3) In (2), preferably, the connecting members are disposed at a front end portion of the base member, the connecting members and the busbars are fixed to each other by fastening members, and elastic engaging portions are formed at a rear end portion of the base member so as to hold the side wall members in an assembled state by elastically engaging with the side wall members. According to this configuration, as the side wall members are held by the base member at two locations, namely the front and rear ends portions of the base member, the assembled state of the base member and the side wall members is stable. As the fastening using fastening members need only be performed at a front end portion of the base member, the workability is improved compared to a case where the fastening members are fastened at both front and rear end portions of the base member.

(4) Preferably, the base member is provided with separation restricting portions for restricting the side wall members from laterally separating from the base member. According to this configuration, as the side wall members are restricted by the separation restricting portions from laterally separating from the base member, the base member and the side wall members can be held in a stable assembled state.

### Details of Embodiments of Present Disclosure

### First Embodiment

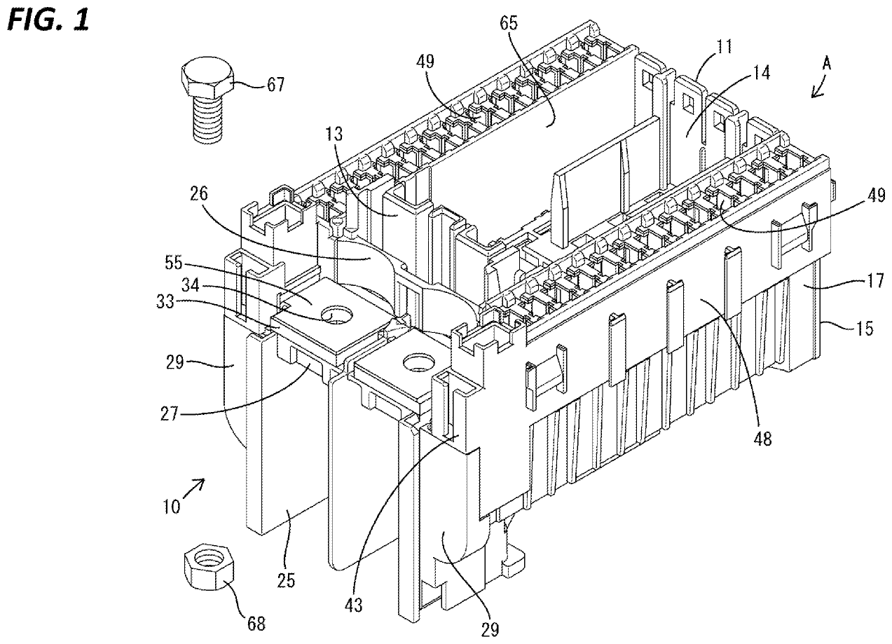

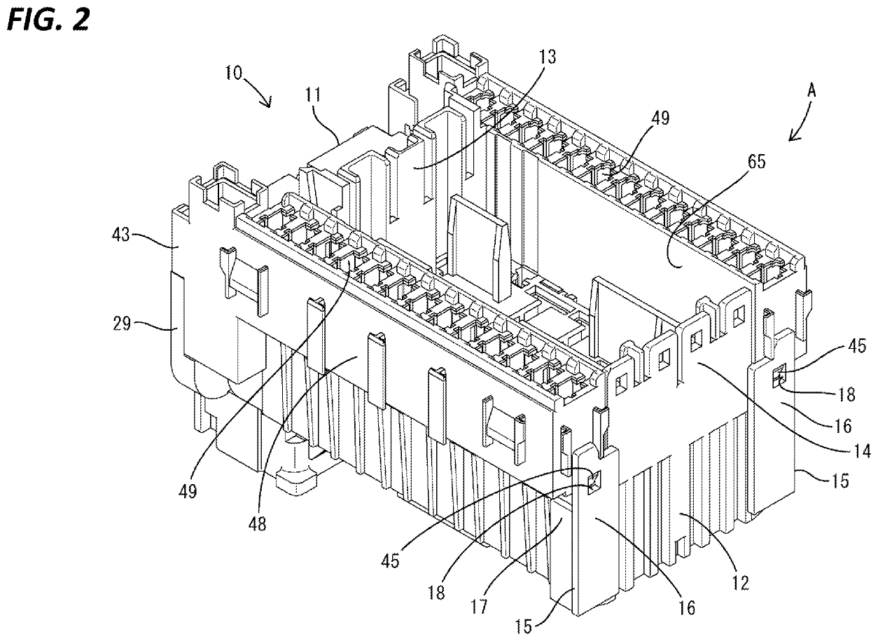

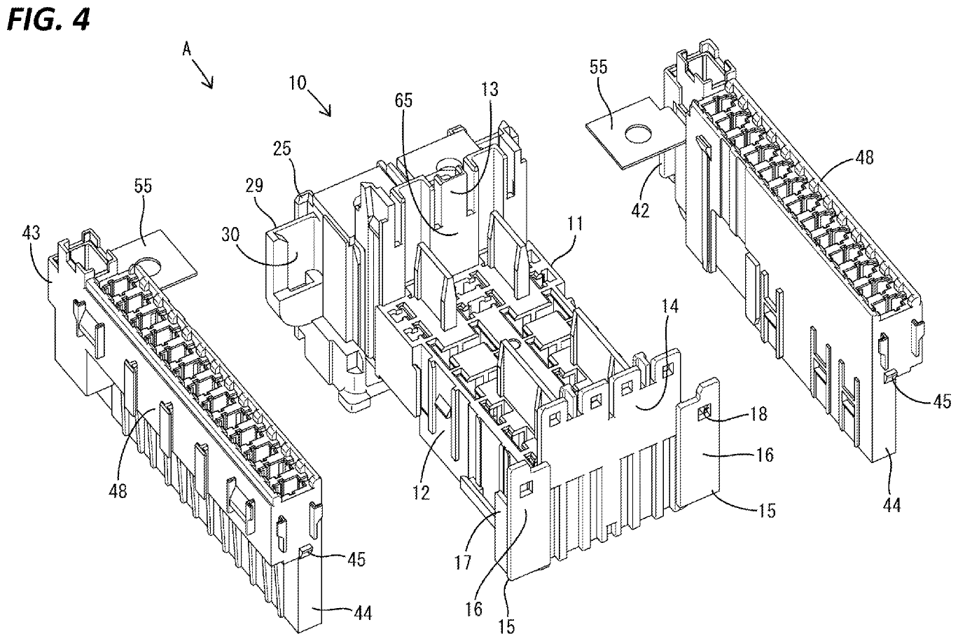

A first embodiment that embodies an electrical junction box of the present disclosure will be described hereinafter with reference to FIGS. 1 to 6. The present invention is not limited by these examples but indicated by the claims, and any modifications within the scope of and meaning equivalent to the claims are intended to be encompassed within the scope of the invention. As for the front and rear directions in the first embodiment, the direction extending obliquely downward and to the left of the electrical junction box A in FIGS. 1, 3, and 5 and the direction extending obliquely upward and to the left in FIGS. 2 and 4 are defined as the front direction. As for the up and down directions, the directions as shown in FIGS. 1 to 5 are defined as upward and downward as-is.

### Overview of Electrical Junction Box A

As shown in FIGS. 1 to 4, the electrical junction box A of the first embodiment includes one base member 10 and a pair of bilaterally symmetrical side wall members 40 that are separate members from the base member 10. The pair of side wall members 40 are assembled to the base member 10 in a positional relationship where they sandwich the base member 10 from the left and right sides. As shown in FIGS. 1 and 2, the electrical junction box A includes a component housing chamber 65 defined by the base member 10 and the pair of side wall members 40. The component housing chamber 65 is open at the upper surface of the electrical junction box A. The component housing chamber 65 is configured to house a plurality of electrical components 66, such as fusible links.

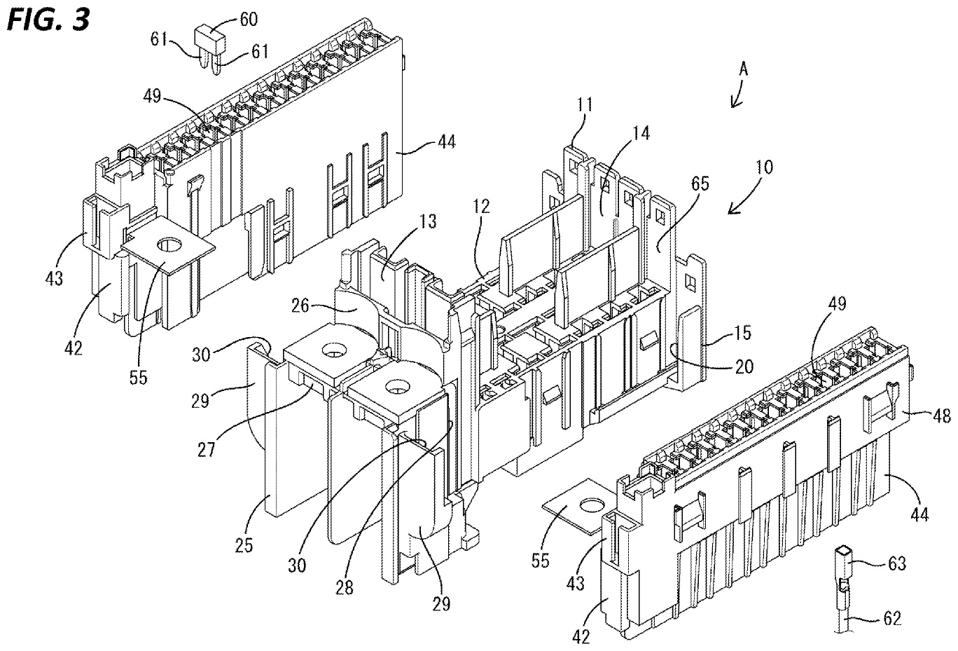

As shown in FIGS. 1 to 5, a pair of left and right front fitting portions 29 are respectively formed at front end portions of the base member 10, and a pair of left and right rear fitting portions 15 are respectively formed at rear end portions of the base member 10. As shown in FIGS. 3 and 4 and 6, a pair of left and right front fit-in portions 42 are respectively formed at front end portions of the side wall members 40, and a pair of left and right rear fit-in portions 44 are respectively formed at rear end portions of the side wall members 40. The base member 10 and the side wall members 40 are held in the assembled state by fitting between the front fitting portions 29 and the front fit-in portions 42 and fitting between the rear fitting portions 15 and the rear fit-in portions 44.

### Base Member 10

The base member 10 includes a holding member 11 made of a synthetic resin, a terminal block 25 made of a synthetic resin that is a separate component from the holding member 11, and a pair of bilaterally symmetrical plates 31 made of metal. As shown in FIGS. 3 to 5, the holding member 11 is a single component that includes a rectangular parallelepiped main body 12 whose long sides are oriented in the front-rear direction, a front plate portion 13 extending upward from the front edge of the main body 12, and a rear plate portion 14 extending upward from the rear edge of the main body 12. The space surrounded by the upper surface of the main body 12, the rear surface of the front panel portion 13, and the front surface of the rear plate portion 14 serves as the component housing chamber 65. In a state where the assembly of the side wall members 40 are not assembled to the base member 10, the component housing chamber 65 is open to the outside of the base member 10 at the upper surface of the base member 10 and at left and right side surfaces of the base member 10.

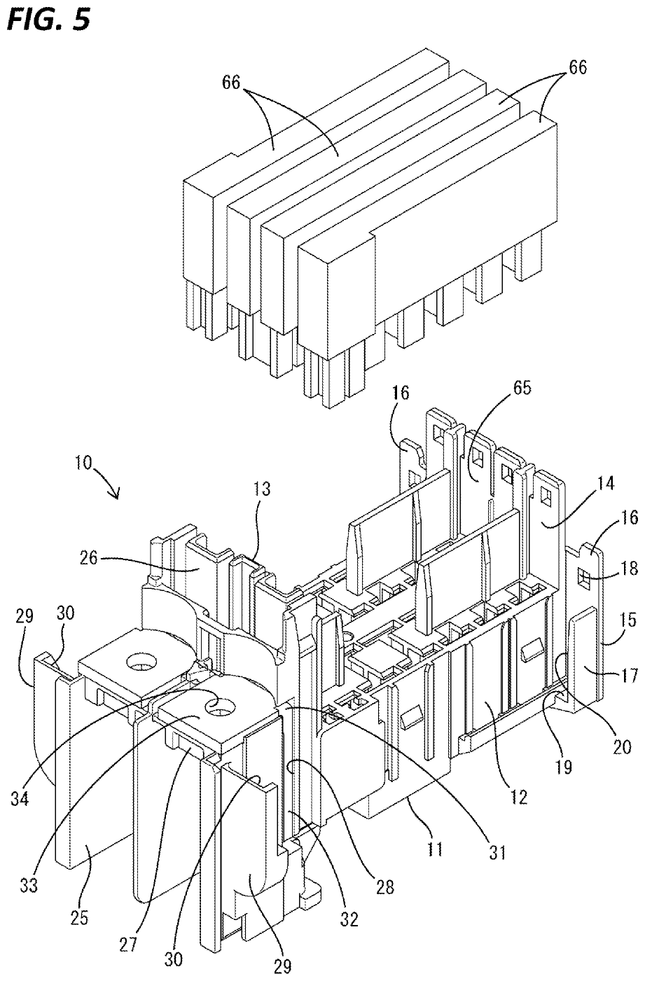

As shown in FIG. 5, a pair of bilaterally symmetrical rear fitting portions 15 are respectively formed at left and right end portions of the rear plate portion 14. The rear fitting portions 15 each include an elastic engaging portion 16 whose thickness direction is oriented in the front-rear direction and a tabular restricting portion 17 whose thickness direction is oriented in the right-left direction. An engaging hole 18 is provided in the rear surface of the elastic engaging portion 16. The side edge portion of the elastic engaging portion 16 is connected to the rear edge portion of the tabular restricting portion 17 at a right angle. The lower edge of the elastic engaging portion 16 and the lower edge of the tabular restricting portion 17 are connected to the outer surface of the lower end portion of the main body 12 via a reinforcing portion 19. The space surrounded by the main body 12, the elastic engaging portion 16, and the tabular restricting portion 17 extends in the up-down direction and serves as a guide groove 20 that is open forward and upward.

The terminal block 25 is a single component that includes a support plate portion 26 whose thickness direction is oriented in the front-rear direction and receiving plate portions 27 whose thickness directions are oriented in the up-down direction. Bolt holes (not shown) are provided so as to vertically extend through each receiving plate portion 27. As shown in FIGS. 3 and 5, the terminal block 25 is assembled to the holding member 11 so as to cover the front side of the front plate portion 13. A pair of left and right housing spaces 28 are formed between the front plate portion 13 of the holding member 11 and the support plate portion 26 of the terminal block 25. The upper end portion of each housing space 28 is open in the form of a slit that extends in the left-right direction and is open to the front side of the base member 10. A pair of bilaterally symmetrical front fitting portions 29 are respectively formed at left and right edges of the terminal block 25. As shown in FIGS. 3 and 4, vertical groove portions 30 are respectively formed on the rear surfaces of the front fitting portions 29. The upper end of each groove portion 30 is open at the upper surface of the terminal block 25.

As shown in FIG. 5, the plates 31 are single components formed by bending an elongated metal member. Each plate 31 includes a tabular power-feeding portion 32 and a tabular mounting portion 33 connected to each other at a right angle. The tabular power-feeding portion 32 has a flat plate shape whose thickness direction is oriented in the front-rear direction. The tabular mounting portion 33 has a flat plate shape whose thickness direction is oriented in the up-down direction and extends forward from the upper edge of the tabular power-feeding portion 32. Mounting holes 34 are provided so as to vertically extend through the tabular mounting portions 33, respectively. The plates 31 are assembled to the base member 10 after the tabular power-feeding portions 32 have been housed in the housing spaces 28, and the tabular mounting portions 33 are exposed to the outside of the housing spaces 28 and set on the receiving plate portions 27. Power-feeding terminals (not shown) connected to a battery (not shown) are to be connected to the tabular power-feeding portions 32.

### Side Wall Member 40

Each side wall member 40 is formed by assembling a main side wall body 41 made of a synthetic resin and a metal busbar 52 to each other. The main side wall body 41 is a single component that is elongated in the front-rear direction and whose wall thickness direction is oriented in the right-left direction as seen in a plan view. As shown in FIGS. 3, 4, and 6, the lower end portion of the front edge portion of each main side wall body 41 serves as the front fit-in portion 42. A stopper 43 that protrudes forward in a stepwise manner is provided at the upper end portion of each front fit-in portion 42. The lower end portion of the rear edge portion of each main side wall body 41 serves as the rear fit-in portion 44. An engaging protrusion 45 is provided on the rear surface of each main side wall body 41.

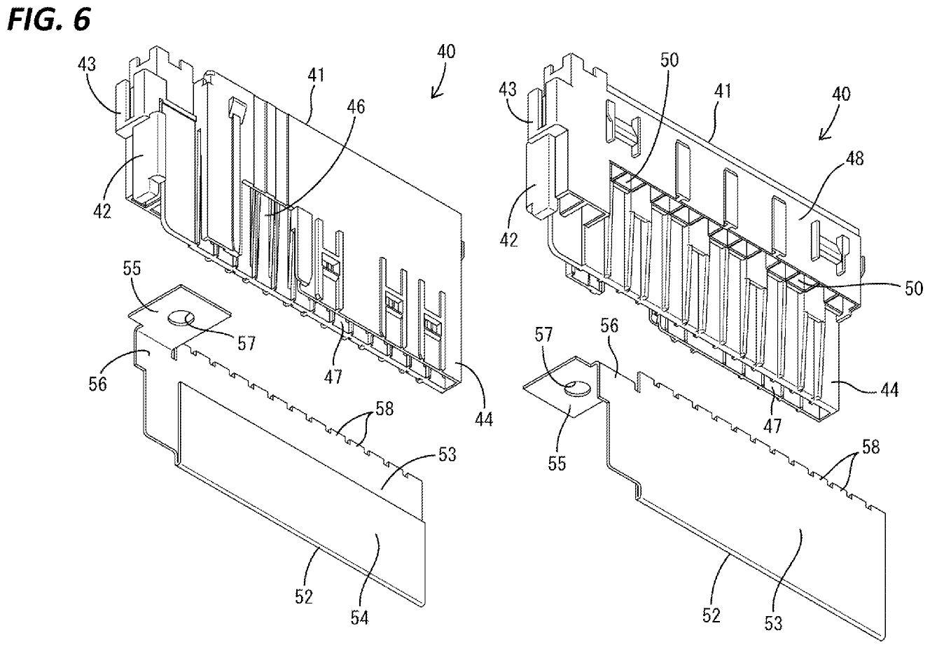

As shown in FIG. 6, busbar housing chambers 46 are respectively formed in the main side wall bodies 41. The busbar housing chambers 46 are narrow spaces having a smaller right-left length compared to the front-rear length and the up-down length thereof. The lower end of each busbar housing chamber 46 is open as a slit-shaped busbar mounting port 47 at the lower surface of the main side wall body 41. Widened portions 48 having a larger width than the lower end portions of the main side wall bodies 41 are formed at the upper end portions of the main side wall bodies 41, respectively. A plurality of fuse housing chambers 49 that are open at the upper surface of the main side wall body 41 is formed in the widened portion 48 so as to be aligned in the front-rear direction. The plurality of fuse housing chambers 49 are in communication with the busbar housing chamber 46. A plurality of cavities 50 are formed in the region of the widened portion 48 below the fuse housing chambers 49 so as to be aligned in the front-rear direction.

Each busbar 52 is a single component made by stamping a metal plate into a predetermined shape and bending it. As shown in FIG. 6, each busbar 52 includes a single base plate portion 53, a single heat dissipation plate portion 54, a single connection plate portion 55, and a plurality of tabs 58. The base plate portion 53 and the heat dissipation plate portion 54 have a rectangular plate shape whose thickness direction is oriented in the right-left direction. The heat dissipation plate portion 54 extends from the lower edge of the base plate portion 53 to overlap the inner surface of the base plate portion 53. The connection plate portion 55 extends horizontally inward from the upper edge of a support portion 56 at the front end portion of the base plate portion 53. A through-hole 57 is formed extending vertically through the connection plate portion 55. The plurality of tabs 58 protrude upward from the upper edge of the base plate portion 53 so as to be aligned at intervals in the front-rear direction.

The busbar 52 is assembled to the main side wall body 41 with the base plate portion 53, the heat dissipation plate portion 54, and the tabs 58 housed in the busbar housing chamber 46 via the busbar mounting port 47. The connection plate portion 55 protrudes to the outside of the main side wall body 41 and protrudes inward of the main side wall body 41 in the width direction, i.e., toward the base member 10. A fuse 60 (see FIG. 3) is mounted to a fuse housing chamber 49 from above the side wall member 40. One lead wire 61 of the fuse 60 is connected to a tab 58 of the busbar 52. A harness terminal 63 connected to an electrical wire 62 is disposed in the cavity 50. The harness terminal 63 is connected to the other lead wire 61 of the fuse 60.

### Procedure for Assembly of Electrical Junction Box A

When assembling the electrical junction box A, with the holding member 11 separated from the terminal block 25, the tabular mounting portions 33 are set on the receiving plate portions 27, and the plates 31 are provisionally held on the terminal block 25. In this state, when the terminal block 25 and the holding member 11 are assembled to each other, the housing spaces 28 are formed between the terminal block 25 and the holding member 11, and the tabular power-feeding portions 32 of the plates 31 are housed in the housing spaces 28, thus completing the assembly of the base member 10.

After the base member 10 is assembled, the electrical components 66 are attached to the holding member 11 from above the base member 10 so as to be housed in the component housing chamber 65. As the component housing chamber 65 is open on both left and right sides of the base member 10, if the operator attaches the electrical components 66 by pinching the left and right sides of the electrical components 66, the fingers pinching the electrical components 66 do not interfere with the base member 10. In this way, the workability during the assembly of the electrical components 66 is improved. Additionally, to attach the electrical components 66 using an automatic machine, if the fingers of the automatic machine hold the electrical components 66 by pinching the left and right sides thereof, the fingers do not interfere with the base member 10.

Next, a pair of side wall members 40 are assembled to the base member 10. During the assembly, the front fit-in portions 42 are inserted and fitted into the groove portions 30 of the front fitting portions 29 from above while the rear fit-in portions 44 are inserted and fitted into the guide grooves 20 of the rear fitting portions 15 from above. When the side wall members 40 enter a predetermined assembly state with the base member 10, the stoppers 43 abut against the upper ends of the front fitting portions 29, and the rear fit-in portions 44 abut against the reinforcing portions 19. By fitting the front fit-in portions 42 into the front fitting portions 29, the side wall members 40 are positioned with respect to the base member 10 in the front-rear and right-left directions. The engagement between the engaging protrusions 45 and the engaging holes 18 restricts the side wall members 40 from disengaging upward relative to the base member 10.

When the side wall members 40 are mounted to the base members 10, the component housing chamber 65 is covered by the side wall members 40 from the left and right sides, and thus the assembly of the electrical junction box A is complete. The component housing chamber 65 is surrounded over its entire circumference from the front, rear, left, and right directions. With the side wall members 40 assembled to the base member 10, the connection plate portions 55 of the busbars 52 are set on the upper surfaces of the tabular mounting portions 33 of the plates 31 from the above. In other words, the direction in which the side wall members 40 are assembled to the base member 10 is the same as the direction in which the connection plate portions 55 are assembled to the tabular mounting portions 33. The plates 31 and the busbars 52 are fixed to the terminal block 25 by screwing and fastening bolts 67, which are inserted though the through-holes 57, the mounting holes 34, and bolt holes (omitted from the view), into nuts 68 provided on the lower surfaces of the receiving plate portions 27. The front end portions of the side wall members 40 are fixed to front end portions of the base member 10 by fixing the connection plate portions 55 to the receiving plate portions 27.

### Functions and Effects of the Embodiment

The electrical junction box A of the present embodiment includes the base member 10, to which the electrical components 66 are attached, and the bilaterally symmetrical pair of side wall members 40 detachably attached to the base member 10. A component housing chamber 65 that is open at the upper surface is formed by the base member 10 and a pair of side wall members 40. The electrical components 66 attached to the base member 10 are configured to be housed in the component housing chamber 65. With the side wall members 40 detached from the base member 10, side surfaces of the component housing chamber 65 are open. According to this configuration, by detaching the side wall members 40 in advance when mounting the electrical components 66 to the base member 10, the side wall members 40 do not become a hinderance. Therefore, the workability during assembly is improved.

The plates 31 are mounted to the base member 10. The busbars 52 are mounted to the side wall members 40. The direction in which the side wall members 40 are assembled to the base member 10 is the same as the direction in which the busbars 52 are assembled to the plates 31. According to this configuration, the assembly of the side wall members 40 to the base member 10 and the assembly of the busbars 52 to the plates 31 can be carried out in a single operation.

The plates 31 are disposed at front end portions of the base member 10. The plates 31 and the busbars 52 are fixed by the bolts 67 and the nuts 68 serving as fastening members. The elastic engaging portions 16, which hold the side wall members 40 in the assembled state by elastically engaging with the side wall members 40, are formed at rear end portions of the base member 10. According to this configuration, as the side wall members 40 are held by the base member 10 at two locations, namely the front and rear end portions of the base member 10, the assembled state of the base member 10 and the side wall members 40 is stable. As the fastening using the bolts 67 and the nuts 68 need only be performed at a front end portion of the base member 10, the workability is improved compared to a case where the fastening members are fastened at both front and rear end portions of the base member 10.

The base member 10 is provided with separation restricting portions that restrict the side wall members 40 from being laterally separated from the base member 10. That is, the front fitting portions 29 having the groove portions 30 are formed at front end portions of the base portion 10. The groove portions 30 serve as the separation restricting portions that allow the front fit-in portions 42 to fit therein to restrict the side wall members 40 from laterally separating from the base member 10. The rear fitting portions 15 with the tabular restricting portions 17 are formed at rear end portions of the base portion 10. The tabular restricting portions 17 serve as separation restriction portions through abutment with the rear fit-in portions 44 to restrict the side wall members 40 from laterally separating from the base member 10. As the side wall members 40 are restricted by these separation restricting portions from laterally separating from the base member 10, the base member 10 and the side wall members 40 can be held in a stable assembled state.

### OTHER EMBODIMENTS

The present invention is not limited to the embodiment described in the above description and the drawings, but is indicated by the scope of claims. The present invention is intended to include any modifications within the scope of and meaning equivalent to the claims and include embodiments, such as those provided below.

In the above embodiment, although separation restricting portions are provided on the base member, the base member may not be provided with separation restricting portions.

In the above embodiment, although the direction in which the side wall members are assembled to the base member is the same as the direction in which the busbars are assembled to the plates, the direction in which the side wall members are assembled to the base member may be different from the direction in which the busbars are assembled to the plates.

### LIST OF REFERENCE NUMERALS

A Electrical junction box
10 Base member
11 Holding member
12 Main body
13 Front plate portion
14 Rear plate portion
15 Rear fitting portion
16 Elastic engaging portion
17 Tabular restricting portion (separation restricting portion)
18 Engaging hole
19 Reinforcing portion
20 Guide groove
25 Terminal block
26 Support plate portion
27 Receiving plate portion
28 Housing space
29 Front fitting portion
30 Groove portion (separation restricting portion)
31 Plate (connecting member)
32 Tabular power-feeding portion
33 Tabular mounting portion
34 Mounting hole
40 Side wall member
41 Side wall main body
42 Front fit-in portion
43 Stopper
44 Rear fit-in portion
45 Engaging protrusion
46 Busbar housing chamber
47 Busbar mounting port
48 Widened portion
49 Fuse housing chamber
50 Cavity
52 Busbar
53 Base plate portion
54 Heat dissipation plate portion
55 Connection plate portion
56 Support portion
57 Through-hole
58 Tab
60 Fuse
61 Lead wire
62 Electrical wire
63 Harness terminal
65 Component housing chamber
66 Electrical component
67 Bolt (fastening member)
68 Nut (fastening member)

1. An electrical junction box comprising:
a base member to which an electrical component is to be attached; and
a pair of left and right side wall members capable of being detachably attached to the base member;
wherein a component housing chamber whose upper surface is open is formed by the base member and the pair of side wall members,
the electrical component attached to the base member is housed in the component housing chamber, and
side surfaces of the component housing are open in a state where the side wall members are detached from the base member.

2. The electrical junction box according to claim 1,
wherein connecting members are attached to the base member,
a busbar is mounted to each of the side wall members, and
a direction in which the side wall members are assembled to the base member is the same as a direction in which the busbars are respectively assembled to the connecting members.

3. The electrical junction box according to claim 2,
wherein the connecting members are disposed at a front end portion of the base member,
the connecting members and the busbars are fixed to each other by fastening members, and
elastic engaging portions are formed at a rear end portion of the base member so as to hold the side wall members in an assembled state by elastically engaging with the side wall members.

4. The electrical junction box according to claim 1,
wherein the base member is provided with separation restricting portions for restricting the side wall members from laterally separating from the base member.
